(19) United States
(12) Patent Application Publication
(10) Pub. No.: US 2026/0347999 A1
(43) Pub. Date: Nov. 5, 2026

(54) TARGET JOINED STATE DETECTING METHOD AND FILM FORMATION APPARATUS

(71) Applicant: SHIBAURA MECHATRONICS CORPORATION, Yokohama-shi, Kanagawa (JP)

(72) Inventor: Yoshinao KAMO, Yokohama-shi, Kanagawa (JP)

(21) Appl. No.: 19/119,896

(22) PCT Filed: Sep. 25, 2024
(86) PCT No.: PCT/JP2024/034235

§ 371 Date: Apr. 10, 2025

(30) Foreign Application Priority Data
Sep. 29, 2023 (JP) 2023-170900

(51) Int. Cl. C23C 14/34

(52) U.S. Cl. CPC C23C 14/3407

(57) ABSTRACT

According to an embodiment, a target joined state detecting method and a film formation apparatus are provided which enable, even if a minor peel-off of a target occurs, a detection of such peel-off. According to an embodiment, a film formation apparatus 1 includes a sealed container in which the workpiece W is carried, a target 231 placed in the sealed container, a target base 232 holding the target 231, a temperature detecting unit detecting a temperature of the target 231 and/or the target base 232 in a predetermined time T2 or T1, a calculating unit 45 calculating a change in temperature over time in the predetermined time based on the detected temperature of the target 231 and/or the target base 232, and a joined state determining unit 46 determining a joined state of the target 231 based on the change in temperature over time in the predetermined time.

### FIELD OF THE INVENTION

The present disclosure relates to a target joined state detecting method and a film formation apparatus.

### BACKGROUND

In manufacturing processes for various products, such as a semiconductor, a display and an optical disk, a thin film like an optical film is formed on a workpiece, such as a wafer or a glass substrate. Thin films can be created by repeating film formation forming a film like a metal on a workpiece, and film processing, such as etching to the formed film, and oxidation or nitridation thereon.

Such film formation and film processing can be performed by various schemes, one of such schemes is to utilize plasma. In the film formation, an inert gas is introduced into a chamber that is a vacuum container in which a target is placed, and DC voltage is applied thereto. Ions of the plasma inert gas are collided with the target, and materials knocked out of the target are deposited on a workpiece to form a film. In the film processing, a process gas is introduced into the chamber in which electrodes are placed, and high-frequency voltage is applied to the electrodes. Film processing is performed by colliding ions of the plasma process gas with the film on the workpiece.

In a known sputter-down type film formation apparatuses, in the film formation processing, a target bonded to the lower surface of a target base via a bonding material is placed on the upper surface of the internal space of the vacuum container, an electric field is formed on the lower-surface side of the target to generate plasma, and the target is sputtered by ions from the plasma. The target is cooled via the target base by a cooling mechanism.

### PRIOR ART DOCUMENT

### Patent Document

Patent Document 1: JP 2017-166032A

### SUMMARY OF INVENTION

### Problems to be Solved by Invention

According to film formation apparatuses, the target may peel off and fall off from the target base due to excessive electric power input to the target, insufficient cooling of the target base by a cooling mechanism, or inadequate compatibility between the target material and the bonding material. In particular, in the case of a sputter down-type film formation apparatus, a fallen target becomes a cause of a long-term operation shutdown and a malfunction of the apparatus.

One possible method for detecting the fall-down of a target is utilizes the cooling mechanism for cooling the target. In the case of a water-cooling type cooling mechanism that utilizes a cooling fluid, a possible method is to detect a temperature Te_out at the drain side of the cooling water for cooling the target, and if that temperature exceeds a threshold, it is determined that the target has fallen down.

However, in cases where the target peels off slowly, the cooling drainage-side temperature Te_out does not change beyond the threshold value, and thus it is difficult to detect a minor peeling of the target.

Embodiments of the present disclosure is made in order to address the above-described technical problems, and an objective is to provide a target joined state detecting method and a film formation apparatus that enable, even if a minor peel-off of a target occurs, a detection of such a peel-off.

### Means to Solve the Problem

A film formation apparatus according to embodiments of the present disclosure performs film formation on a workpiece utilizing plasma, and this film formation apparatus includes:
a sealed container in which the workpiece is carried;
a target placed in the sealed container;
a target base that holds, on one surface, the target;
a temperature detecting unit that detects a temperature of the target and/or the target base in a predetermined time after an end of film formation processing or in a predetermined time from a start of the film formation processing after a certain time has elapsed from the end of the film formation processing;
a calculating unit that calculates a change in temperature over time in the predetermined time based on the detected temperature of the target and/or the target base; and
a joined state determining unit that determines a joined state of the target based on the change in temperature over time in the predetermined time.

Moreover, a target joined state detecting method according to embodiment of the present disclosure is a target joined state detecting method of a film formation apparatus that executes film formation on a workpiece utilizing plasma, and the method includes:
a temperature detecting step of detecting a temperature of the target and/or a target base in a predetermined time after an end of film formation processing or in a predetermined time from a start of the film formation processing after a certain time has elapsed from the end of the film formation processing;
a calculating step of calculating a change in temperature over time in the predetermined time based on the detected temperature of the target and/or the target base; and
a joined state determining step of determining a joined state of the target based on the change in temperature over time in the predetermined time.

### Effects of Invention

The film formation apparatus of the present disclosure enables, even if a minor peel-off of a target occurs, a detection of such a peel-off.

### BRIEF DESCRIPTION OF DRAWINGS

FIG. 1 is a schematic diagram illustrating a film formation apparatus according to a first embodiment;

FIG. 2A is a perspective view and FIG. 2B is a bottom plan view both illustrating a cooling plate according to the first embodiment;

FIG. 3 is a block diagram illustrating a structure of a control device according to the first embodiment;

FIG. 4 is a graph showing an in/out temperature difference of a cooling water for a decent target stored in a reference temperature storing unit according to the first embodiment;

FIG. 5 is a graph showing the in/out temperature difference of the cooling water representing that a steady operation is executed across a certain time period and a target becomes a steady state;

FIG. 6 is a graph showing a change pattern of the in/out temperature difference of the cooling water in a decent target and that in a damaged target;

FIG. 7 is a flowchart illustrating a target joined state detecting process according to the first embodiment;

FIG. 8A is a graph showing the change pattern of the in/out temperature difference of the cooling water in a decent target and in a damaged target, and FIG. 8B is a graph corresponding to the change pattern of the in/out temperature difference of the cooling water in FIG. 8A and showing ON and OFF of an applied voltage by a power supply device;

FIG. 9 is a schematic diagram illustrating a film formation apparatus according to a modification of the first embodiment;

FIG. 10 is a graph showing a change pattern of an integrated heat dissipation quantity of a decent target and of a damaged target in a predetermined time;

FIG. 11 is a block diagram illustrating a structure of a control device according to the modified example of the first embodiment;

FIG. 12 is a block diagram illustrating a structure of a control device according to the modified example of the first embodiment;

FIG. 13 is a graph showing a heat dissipating rate relative to an elapsed time from a heat input termination in the modified example according to the first embodiment;

FIG. 14 is a schematic diagram illustrating a film formation apparatus according to a second embodiment;

FIG. 15 is a block diagram illustrating a structure of a control device according to the second embodiment;

FIG. 16 is a graph showing a simulation of a correlation between the temperature of a target and the temperature of a target base, both changing over time after a film formation processing that utilizes a Cr target in the film formation apparatus according to the second embodiment;

FIG. 17 is a flowchart illustrating a target joined state detecting process in the second embodiment; and

FIG. 18 is a graph showing a correlation between a target temperature and a target base temperature.

### EMBODIMENTS

Embodiments of the present disclosure (will be referred to “this embodiment”, respectively) will be described in detail with reference to the figures. Note that those figures are merely schematic, and the size of each component, a ratio, etc., and include parts that are overdrawn so as to make them easier to understand.

### 1. First Embodiment

### 1-1. Structure

A first embodiment according to the present disclosure will be described with reference to the drawings.

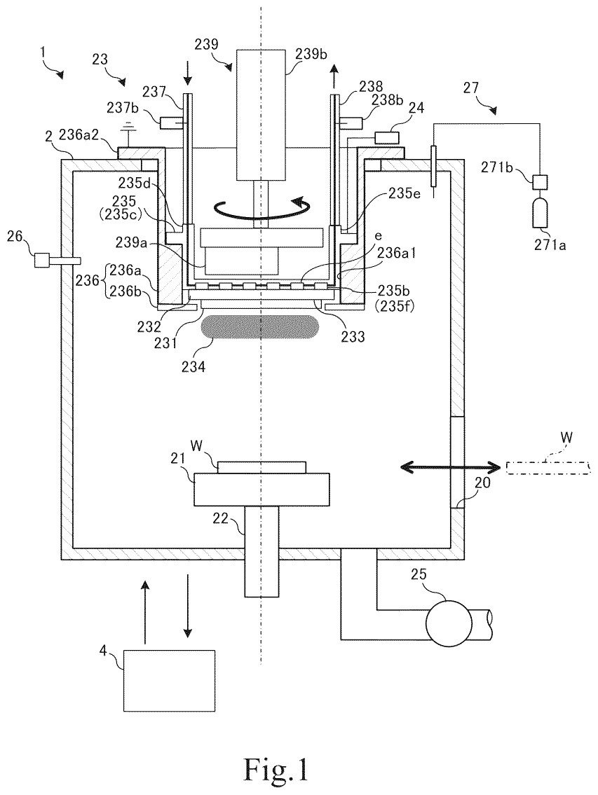

A film formation apparatus 1 is a film formation apparatus that performs film formation on a workpiece W by using plasma. As illustrated in FIG. 1, the film formation apparatus 1 has a stage 21 on which the workpiece W is placed and which is positioned near the bottom of a chamber 2 that is a sealed container. The kind of the workpiece W is not limited to any particular kind, and is, for example, a glass substrate.

The stage 21 is disk-shaped, and is connected to and supported by a shaft 22 that extends from the bottom surface of the chamber 2. The shaft 22 airtightly passes through the bottom surface of chamber 2, and communicates with the exterior. The chamber 2 is provided with a discharging device 25 and a pressure gauge 26. An example discharging device 25 is a pump, and constantly discharges gas inside the chamber 2 so as to maintain a depressurized state. The pressure gauge 26 measures pressure inside the chamber 2.

The chamber 2 is provided with a carry in-and-out port 20 for the workpiece W. The carry in-and-out port 20 is connected to an unillustrated load-lock chamber, and the workpiece W is carried inside the chamber 2 through the load-lock chamber from the exterior of the film formation apparatus 1. The load-lock device is also provided with a discharging device. When the workpiece W is to be carried in the chamber 2, the load-lock chamber is depressurized to preset pressure after the workpiece W is carried in the load-lock chamber. After the depressurization to the preset pressure, the carry in-and-out port 20 of the chamber 2 is opened, and the workpiece W is carried in the chamber 2. The pressure rise inside the chamber 2 can be suppressed by opening the carry in-and-out port 20 after the depressurization to the preset pressure.

A sputter source 23 is placed at the upper part of the chamber 2. The sputter source 23 is a supply source of a film formation material which is deposited on the workpiece W so as to form a film. The sputter source 23 includes a target 231, a target base 232, a bonding portion 233, a cooling plate 235, an anode portion 236, a water supply portion 237, a water drain portion 238, and a magnet portion 239. Note that a power supply device 24 is connected to the sputter source 23.

The target 231 is provided at the lower part of the sputter source 23, and is placed so that its surface faces the stage 21 which is provided near the bottom of the chamber 2. That is, the target 231 is provided in the chamber 2. The target 231 is formed of a film formation material, and all kinds of known film formation materials are applicable. In this embodiment, chromium (Cr) is applied as the target 231. An example shape of the target 231 is a circular cylindrical shape. However, other shapes, such as an elliptic cylinder shape, and a rectangular column shape, are also applicable.

The upper surface of the target 231 is held on, via the bonding portion 233, one surface of the target base 232. The target base 232 forms a cathode together with the target 231. An example target base 232 is a copper plate. The target base 232 has a surface at the opposite side to the stage 21 held by the cooling plate 235. The bonding portion 233 is a bonding layer that bonds the target 231 with the target base 232 by a bonding material like In, or In alloy.

When sputtering is started, ions in plasma collide with the target 231. The particles of the film formation material are flied out of the target 231 by the colliding ions, and are deposited on the workpiece W that is a substrate subjected to film formation, and thus a thin film is formed. A sputter gas becomes plasma, and becomes a heat source 234 by applying a DC voltage to the target 231 during film formation. During a sputtering operation, the surface of the target 231 becomes a high temperature due to the effect of the heat source 234. The target 231 is cooled by the cooling plate 235, and thus melting of the bonding portion 233, stress due to a difference between the thermal expansion of the material of the target 231 and that of the bonding portion 233, and further a peel-off of the target 231 from the target base 232 inherent thereto are suppressed.

The cooling plate 235 has a role of cooling the target 231. For example, the cooling plate 235 indirectly cools a cooling object through a cooling fluid. In this embodiment, cooling water e as a cooling fluid flows in the cooling plate 235, and the target 231 is cooled uniformly through the target base 232. The cooling plate 235 is formed in, for example, a cylindrical shape that has one end blocked off. A surface that holds the other surface of the target base 232 is provided at the end surface of the one end. A flange 235c, a water supply opening 235d and a water drain opening 235e are provided in the other end of the cooling plate 235.

The flange 235c is formed at the other end of cooling plate 235 so as to extend outwardly. The flange 235c is airtightly connected to a thickened portion 236al of a T-S distance adjusting portion 236a via an unillustrated insulating member. The supply opening 235d is water connected to the water supply portion 237, and is to introduce the cooling water e into the interior of the cooling plate 235. The water drain opening 235e is connected to water drain portion 238, and is to drain the cooling water e supplied to the interior of the cooling plate 235.

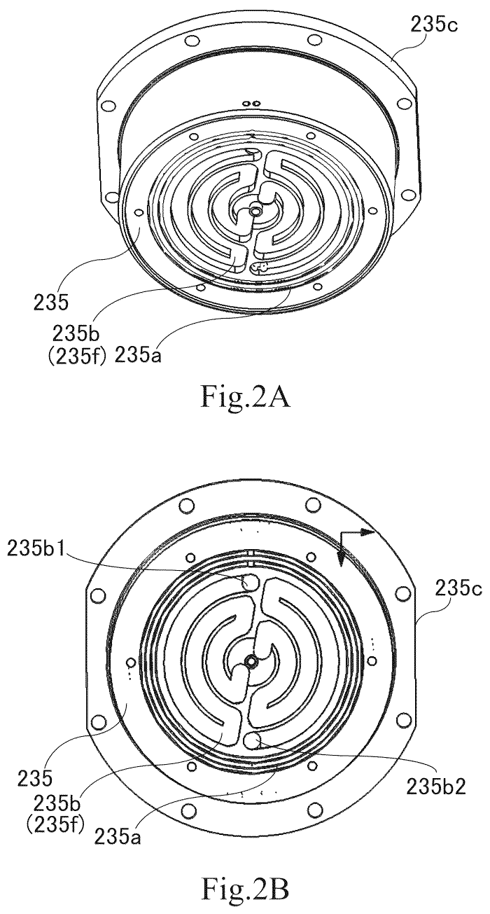

The surface (a front surface) of the cooling plate 235 to hold the target base 232 is larger than a surface of the target 231. As illustrated in FIGS. 2A and 2B, formed in the surface of the cooling plate 235 is a recessed groove 235b. The groove 235b is formed, in the surface of the cooling plate 235, within a range that is greater than or equal to the area of at least the surface of the target 231, and within a range that is smaller than the area of the surface of the cooling plate 235. The groove 235b includes an inlet 235b1 and an outlet 235b2. The inlet 235b1 is connected to the water supply opening 235d, and the outlet 235b2 is connected to the water drain opening 235e. The groove 235b runs throughout the above-described ranges in the surface of the cooling plate 235, and communicates from the inlet 235b1 to the outlet 235b2. When the groove 235b is provided in the surface of the cooling plate 235, a sealing member 235a like an O-ring is provided on the surface of cooling plate 235 so as to surround the groove 235b. The cooling plate 235 is fastened to the target base 232 via the sealing member 235a like an O-ring. A flow path 235f for the cooling water e is formed by the groove 235b and by the fastened target base 232. Since the formed flow path 235f is sealed by the sealing member 235a, the cooling water e flows in the flow path 235f without leaking from a connected portion. Note that in this embodiment, although the flow path 235f is formed by the groove 235b of the cooling plate 235 and by the target base 232, this case is also included in a provision that the flow path 235f is provided in the cooling plate 235.

Moreover, the flow path 235f may be provided inside the cooling plate 235. In this case, since the cooling water e does not leak from the connected portion with the target base 232, the target base 232 and the cooling plate 235 may be connected to each other without the sealing member 235a.

The anode portion 236 suppresses the production of the plasma other than the surface of the target 231, and functions as an anode for the target 231 and for the target base 232. The anode portion 236 is composed of the T-S distance adjusting portion 236a and an anode ring 236b.

The T-S distance adjusting portion 236a is a member capable of adjusting a distance (a T-S distance) between the target 231 and the workpiece W. The T-S distance adjusting portion 236a is formed in, for example, a cylindrical shape. One end of the T-S distance adjusting portion 236a is inserted to the interior of the chamber 2 through the opening in the upper surface of the chamber 2. The one end of the T-S distance adjusting portion 236a has the thickened portion 236a1 that has an inner circumference thickened across the entire circumference. The flange 235c of the cooling plate 235 is airtightly connected to the thickened portion 236a1 via an unillustrated insulating member. By employing such a structure, the target 231, the target base 232, the cooling plate 235 and the magnet portion 239 are placed at the internal side of the anode portion 236. The other end of the T-S distance adjusting portion 236a is provided outside the chamber 2. The other end of the T-S distance adjusting portion 236a includes a flange 236a2 protruding in an annular shape so as to increase the diameter outwardly. The T-S distance adjusting portion 236a is airtightly connected to the chamber 2 through the flange 236a2.

By changing the length between the thickened portion 236a1 and the flange 236a2, the T-S distance adjusting portion 236a can change the T-S distance. For example, a plurality of the T-S distance adjusting portions 236a having different lengths between the thickened portion 236al and the flange 236a2 is prepared in advance. The T-S distance can be changed arbitrarily by properly utilizing the respective T-S distance adjusting portions 236a having different lengths between the thickened portion 236a1 and the flange 236a2. Alternatively, by providing an unillustrated spacer between the flange 236a2 of the T-S distance adjusting portion 236a and the chamber 2, the T-S distance may be changed. For example, the T-S distance can be changed by changing the thickness of the unillustrated spacer. Note that, the T-S distance adjusting portion 236a is grounded.

The anode ring 236b suppresses the production of plasma at any places other than the surface of the target 231, and functions as an anode to the target 231 and to the target base 232. The anode ring 236b is formed in, for example, a ring shape. The anode ring 236b is connected to the one end of the T-S distance adjusting portion 236a, and is provided so as to surround the target 231. This prevents argon molecules from colliding with the target base 232, etc.

The water supply portion 237 supplies the cooling water e to the flow path 235f of the cooling water e formed in the cooling plate 235. The water drain portion 238 drains the cooling water e that has flowed through the flow path 235f of the cooling water e. That is, the water supply portion 237 and the water drain portion 238 are connected to the flow path 235f of the cooling plate 235. The water supply portion 237 and the water drain portion 238 are provided with respective temperature sensors 237b and 238b. The temperature sensors 237b and 238b correspond to a temperature detecting unit, and are connected to the control device 4. The detected temperatures by the temperature sensors 237b and 238b (temperatures Te of the cooling water e) are transmitted to the control device 4 as a supply-side temperature Te in of the cooling water e and a drain-side temperature Te_out of the cooling water e. Note that the supply-side temperature Te_in of the cooling water e will be also referred to as a temperature Te_in of the cooling water e or simply a temperature Te_in, and the drain-side temperature Te_out of the cooling water e will be also referred to as a temperature Te_out of the cooling water e or simply a temperature Te_out.

The magnet portion 239 encloses electrons in a magnetic field, and has a function of creating a space with a high electron density near the surface of the target 231. The magnet portion 239 includes a magnet 239a and a motor 239b. The magnet 239a produces a magnetic field near the surface of the target 231. The magnet 239a is eccentrically rotated, by the motor 239b, around the rotation shaft of the motor 239b. The magnet 239a is placed on the back surface of the target 231 via the cooling plate 235, and is a permanent magnet that produces a rotational magnetic field. The motor 239b is a drive source that rotates the magnet 239a. The motor 239b is connected to an unillustrated power supply device, and causes the magnet 239a to eccentrically rotate, thereby changing the magnetic field near the surface of the target 231. By changing the magnetic field near the surface of the target 231, the plasma density near the surface of the target 231 can be also changed. Consequently, the eroded region by sputtering in the surface of the target 231 can be shifted, and thus excessive erosion and heating to a particular portion of the target 231 are suppressed.

The power supply device 24 is a structural component that applies a voltage to the target 231 through the target base 232. That is, the power supply device 24 causes the sputter gas introduced around the target 231 to be plasma by applying a voltage to the target 231, and causes the film formation material to be deposited on the workpiece W. The power supply device 24 in this embodiment is, for example, a DC power supply that applies a high voltage. In this embodiment, the power supply device 24 is connected to the cooling plate 235. Hence, the power supply device 24 is connected to the target base 232 via the cooling plate 235. Note that in the case of an apparatus that performs high-frequency sputtering, the power supply device 24 may be an RF power supply.

Moreover, a sputter gas introducing portion 27 is provided at the chamber 2. The sputter gas is introduced from this sputter gas introducing portion 27 to the interior of the chamber 2. The sputter gas is not limited to any particular gas, but in this embodiment, for example, an inert gas like argon is applicable. The sputter gas introducing portion 27 includes an argon gas introducing portion 271a, and a flow-volume control gauge 271b. The argon gas introducing portion 271a is a supply source of argon gas like a tank. The flow-volume control gauge 271b measures and controls the flow volume of the argon gas, thereby introducing the argon gas inside the chamber 2 at a predetermined flow volume.

### [Control Device]

The control device 4 controls the operation of each component of the film formation apparatus 1. This control device 4 is accomplished by, for example, a special-purpose electronic circuit or a computer that is run by a predetermined program. The control details for each component are programmed in the control device 4, and are executed by a processing device, such as a PLC or a CPU. Hence, it is compatible with the wide varieties of the film formation specification.

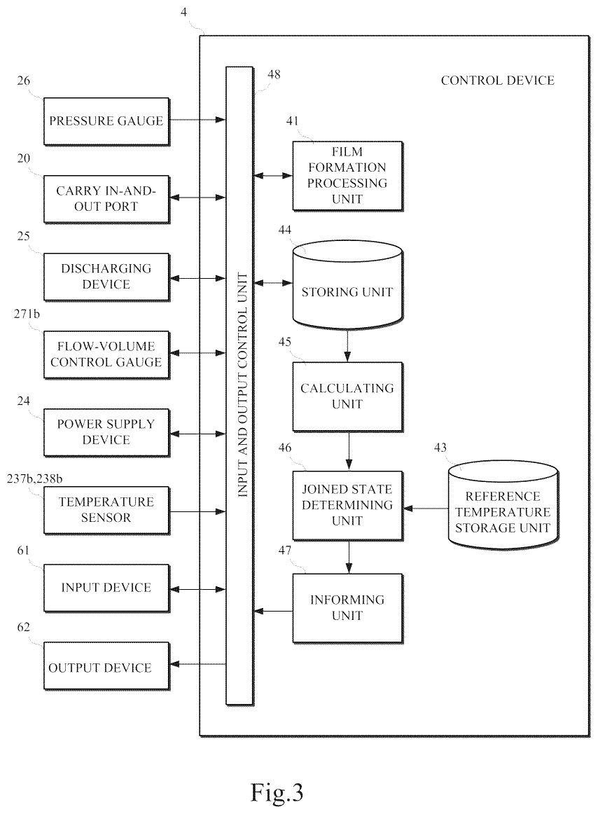

Moreover, the control device 4 has a function of determining the joined state of the target 231 based on a temperature change over time of the target 231 and/or the target base 232, i.e., a temperature change pattern of the target 231 and/or the target base 232 in a predetermined time T2 after the end of the film formation processing or in a predetermined time T1 from the start of the film formation processing after a certain time Tsp has elapsed from the end of the film formation processing. The structure of such a control device 4 will be described with reference to FIG. 3 that is a virtual functional block diagram. The control device 4 includes a film formation processing unit 41, a reference temperature storing unit 43, a storage unit 44, a calculating unit 45, a joined state determining unit 46, an informing unit 47 and an input and output control unit 48.

The film formation processing unit 41 is a processing unit that controls the mechanism of each component of the film formation apparatus 1 to perform film formation processing. Example control details are opening and closing of the load-lock chamber, a control for the pressure inside the load-lock chamber, a control for the pressure inside chamber 2, opening and closing of the carry in-and-out port 20, a discharging speed by the discharging device 25, a control for an introducing timing and an introducing volume by the sputter gas introducing portion 27, a control for the voltage applying timing and the supplied electric power amount by the power supply device 24, and a control for a timing for detecting a temperature change over time of the target 231 and/or the target base 232.

The film formation processing unit 41 obtains pressure inside the chamber 2 from the pressure gauge 26, and checks whether the pressure in the chamber 2 reaches base pressure or not. The base pressure is pressure in the chamber 2 at which the sputter gas can be introduced. More specifically, after the workpiece Wis carried in the chamber 2 and the carry in-and-out port 20 is closed, the pressure in the chamber 2 is reduced to the base pressure by performing discharging by the discharging device 25 for a preset time. After the pressure reaches the base pressure, the sputter gas introducing portion 27 controls the flow-volume control gauge 271b for the argon gas so as to introduce, at the predetermined flow volume, the argon gas in the chamber 2. Consequently, the interior of the chamber 2 becomes arbitrary pressure.

The reference temperature storing unit 43 is storing means like a memory. The reference temperature storing unit 43 stores, in association with an elapsed time T, the temperature change of a decent target in the predetermined time T1 from the start of the film formation processing after the certain time Tsp has elapsed from the end of the film formation processing, or the predetermined time T2 after the end of the film formation processing. The term decent target means a target in a state in which no peel-off due to melting or stress has occurred at the bonding portion 233, and thus a peel-off of the target 231 has not occurred.

Note that the expression “peel-off” of the target 231 means either one or both of the peel-off of the target 231 from the bonding portion 233 and the peel-off of the target base 232 from the bonding portion 233. In this case, the “peel-off of the target 231” includes the wide varieties of peel-offs from a minor peel-off that is an initial stage of the peel-off (a quite small peel-off in the initial stage) to a large peel-off resulting in the falling of the target 231. Note that a minor peel-off before the target 231 falls, which will be described later, means a peel-off which is larger than a quite small peel-off in the initial stage and which is smaller than a large peel-off resulting in the falling of the target 231.

It is preferable that a value that becomes an index to determine a minor peel-off before the target 231 falls is a value with a certain level of margin relative to a value that becomes an index to determine a large peel-off resulting in the falling of the target 231. That is, it may be determined that a peel-off has occurred when it reaches the value that becomes an index for a minor peel-off before it reaches the value that is an index for a large peel-off. For example, the absolute value of the “slope of the temperature curve” in the case of a large peel-off may be acquired in advance by experiments, and a value which has a margin relative to the foregoing value and which becomes a large value when compared with the absolute value may be set as the value that becomes an index for a minor peel-off. Hence, when a peel-off is detected at a time point when it becomes the value that becomes an index for a minor peel-off, the falling of the target 231 is preventable. Moreover, a difference between the value that becomes an index for a minor peel-off and the absolute value of the slope of the temperature curve of the decent target may be acquired, and a determination may be made such that a peel-off has not occurred when the difference of the slope is within such a value.

Moreover, the predetermined time T1 is a predefined time from the start of the film formation processing after the certain time Tsp has elapsed from the end of the film formation processing, and the predetermined time T2 is a predefined time after the end of the film formation processing. The predetermined time T1 and the predetermined time T2 can be defined as appropriate in accordance with the condition of the film formation and with the base material of the target. Note that, the term “predetermined” in this embodiment means to be set in advance in the storing means of the control device 4, and the term “predetermined time” can be also read as a “set time” that is set in advance. Moreover, the certain time Tsp is a time until the heated target 231 is cooled to an ordinary temperature. An example certain time Tsp is longer than or equal to 180 seconds(s), and in this embodiment, the certain time Tsp is 180 s. The certain time Tsp is also set in advance in the storing means, etc., of the control device 4.

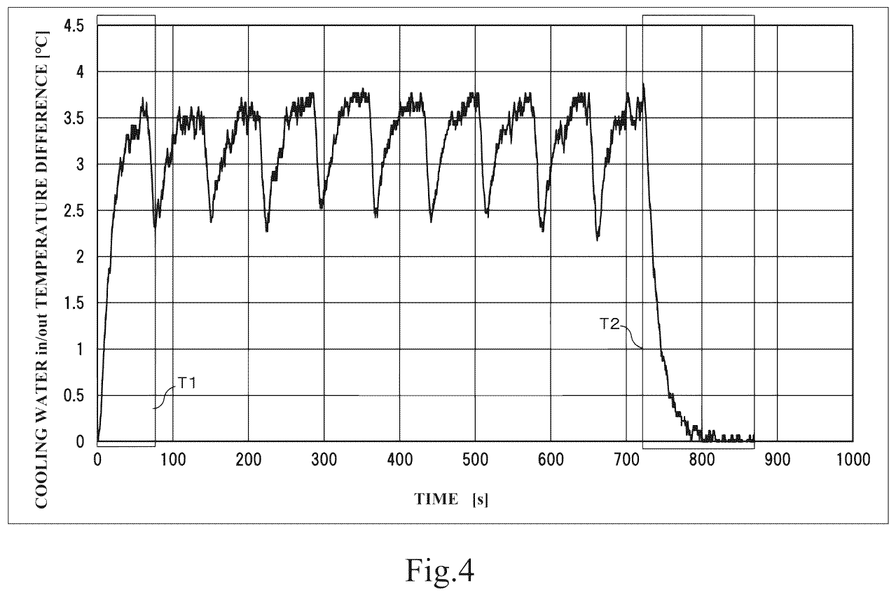

As for the temperature change of the decent target, the temperature of the target 231 that is directly measured, or the temperature of the target 231 that is indirectly measured may be adopted. As for a method of indirectly measuring the temperature change of the decent target, a method of applying the temperatures Te of the cooling water e before and after the target 231 is cooled, i.e., the temperature Te_in and the temperature Te_out are adoptable. For example, a method of calculating a temperature difference (an in/out temperature difference of the cooling water e) between the temperature Te_in and the temperature Te_out is applicable. That is, the temperature sensors 237b, 238b detect the temperature of the target 231 and/or the target base 232 in predetermined time T2 after the end of the film formation processing, or in the predetermined time T1 from the start of the film formation processing after the certain time Tsp has elapsed from the end of the film formation processing. Note that in the following description, the in/out temperature difference of the cooling water e will be also referred to as a cooling water in/out temperature difference or simply an in/out temperature difference. FIG. 4 is a graph showing the in/out temperature difference of the cooling water e for the decent target stored in the reference temperature storing unit 43. FIG. 4 shows the in/out temperature difference of the cooling water e in a time period from immediately after the start of the film formation processing and until 180 seconds have elapsed from the end of the film formation processing. In the graph, it is defined that a time period from the start of the film formation processing until 80 seconds have elapsed (0 s to 80 s) is the predetermined time T1, and a time period from the end of the film formation processing until 180 seconds have elapsed (710 s to 890 s) is the predetermined time T2.

Note that the film formation processing in FIG. 4 represents a case in which the film formation with a short film formation time has been performed on the plurality of workpieces W. A necessary time for a single film formation in this case is 65 seconds. Moreover, a case in which the film formation time is short means a case in which the target 231 is not becoming the steady state.

Moreover, as shown in FIG. 4, when the film formation is repeatedly performed by several times, the whole film formations repeatedly performed by several times will be referred to as the “film formation processing”. In this case, in a single film formation among the repeated film formations by several times, starting the film formation will be referred to as the “start of the film formation”, and ending the film formation will be referred to as “the end of the film formation”, Moreover, among the repeated film formations by several times, the start of the first film formation will be referred to as the “start of the film formation processing”, and the end of the last film formation will be referred to as the “end of the film formation processing”. Furthermore, the film formation processing means a state in which one film formation and the next film formation is divided by the certain time Tsp. Hence, only a single film formation may be executed by the single film formation processing, and the “start of the film formation processing” will be also referred to as the “start of the film formation processing after the certain time Tsp has elapsed from the end of the film formation processing”.

The storage unit 44 is to store the temperature of the target 231 subjected to the determination. When the temperature of the target 231 is indirectly measured, the temperature Te_in and the temperature Te_out detected at the water supply portion 237 and at the water drain portion 238, respectively, are stored. When the film formation processing starts, the temperature Te_in and the temperature Te_out are transmitted to the control device 4 from the temperature sensor 237b temperature sensor 238b, respectively. The storage unit 44 stores the temperature Te_in and the temperature Te_out for the predetermined time (for the predetermined time T1 or by the predetermined time T2) from the start of the film formation processing or the end of the film formation processing. Note that, the storage unit 44 may store the temperature Te_in and the temperature Te_out detected at the water supply portion 237 and at the water drain portion 238, respectively, until the film formation processing ends from the start of the film formation processing. Alternatively, the storage unit 44 may store the temperature Te_in and the temperature Te_out detected at the water supply portion 237 and at the water drain portion 238, respectively, while the film formation apparatus 1 is in operation.

The calculating unit 45 is a calculation unit that calculates the in/out temperature difference of the cooling water e from the temperature Te_in and the temperature Te_out, both stored in the storage unit 44, and arranges it for each elapsed time t. That is, the calculating unit 45 calculates a change in temperature over time in the predetermined time T1 (T2) based on the temperature Te_in and on the temperature Te_out (the detected temperature of the target 231 and/or the target base 232). The in/out temperature difference calculated by the calculating unit 45 may be only for the predetermined time T1 or for the predetermined time T2, but in the following description, for the sake of explanation, the in/out temperature difference is calculated immediately after the start of the film formation process until 300 seconds have elapsed after the end of the film formation processing.

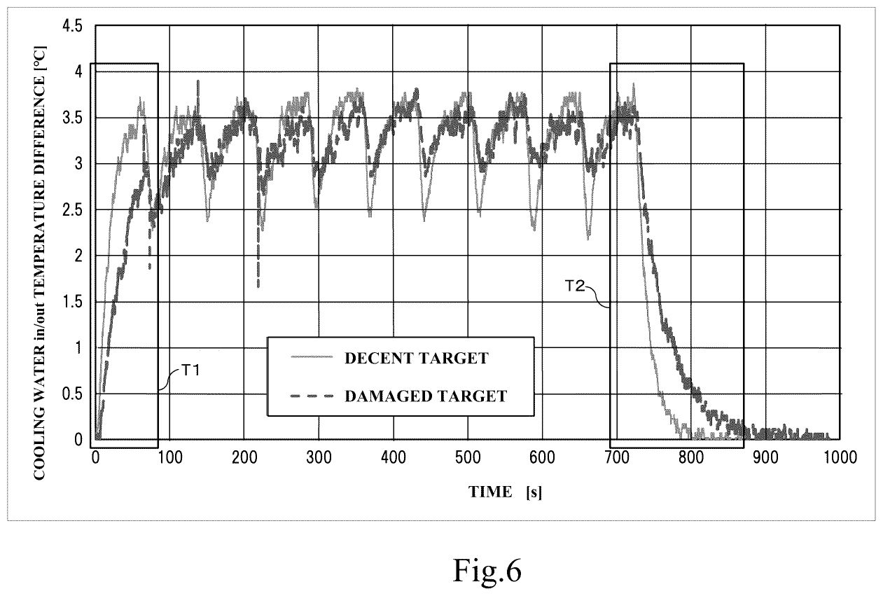

The joined state determining unit 46 compares the in/out temperature difference of the cooling water e for the decent target stored in the reference temperature storing unit 43 with the in/out temperature difference of the cooling water e at the target 231 attached to the film formation apparatus 1, and determines the joined state of the target 231. That is, the joined state determining unit 46 is a determining unit that determines the joined state of the target 231 based on a temperature change over time in the predetermined time T1 (T2). For example, as illustrated in FIG. 6, the joined state determining unit 46 compares the slope of the plots of the in/out temperature difference (a temperature curve) of the cooling water e for the decent target with that of the in/out temperature difference of the cooling water e for the target 231 attached to the film formation apparatus 1 in the predetermined time T1 or in the predetermined time T2 to make a determination. The specific determination method will be described later.

The informing unit 47 informs, when a minor peel-off before the target 231 falls is detected, an output device 62 to be described later of such a detection. The input and output control unit 48 is an interface that controls conversion, input, and output of signals between the components to be controlled.

Furthermore, an input device 61 and the output device 62 are further connected to the control device 4. The input device 61 is input means, such as a switch, a touch panel, a keyboard, and a mouse, that allow the user to operate the film formation apparatus 1 through the control device 4.

The output device 62 is output means, such as a display, a lamp and a meter that enable the user to visually recognize information for checking the state of the film formation apparatus 1, and, a speaker and buzzer that enable the user to auditory recognize such information.

### 1-2. Actions

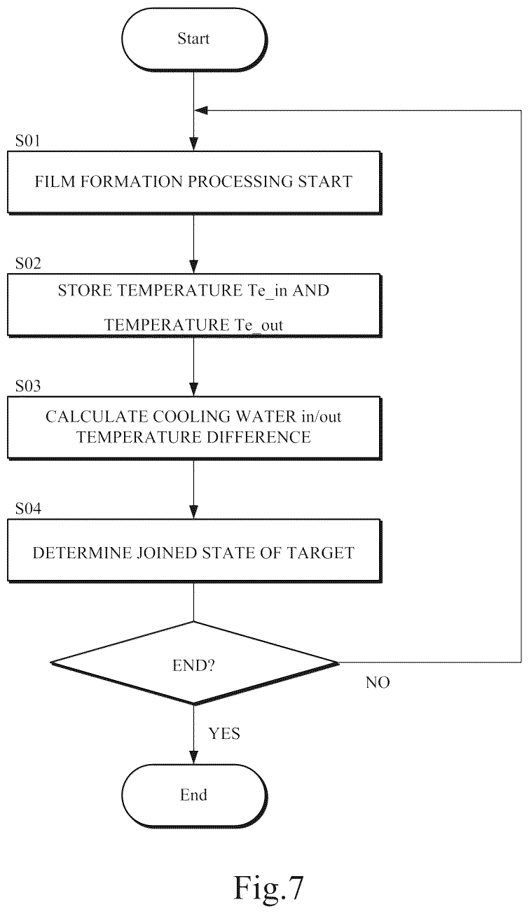

Next, the operations of the film formation apparatus 1 according to this embodiment and the film formation method thereof will be described with reference to FIG. 7. The operations of the film formation apparatus 1 to be described below are controlled by the film formation processing unit 41 of the control device 4. In the following description, a Cr target with φ150 mm×t 10 mm is adopted.

The workpiece W is carried in the unillustrated load-lock chamber from the exterior at atmospheric pressure. After the load-lock chamber is depressurized to the preset pressure, the carry in-and-out port 20 is opened, and the workpiece W is carried in the chamber 2. The carried workpiece W is mounted on the stage 21. The carrying of the workpiece w to the chamber 2 is performed by an unillustrated carrying device. After the workpiece W is mounted on the stage 21, the carry in-and-out port 20 is closed to airtightly seal the chamber 2. Since the chamber 2 is always discharged by the discharging device 25, the chamber 2 is depressurized by closing the carry in-and-out port 20.

The control device 4 acquires the pressure value in the chamber 2 from the pressure gauge 26 when the counted time has elapsed a predetermined discharging time since the carry in-and-out port 20 was closed. When the pressure in the chamber 2 is lower than or equal to the base pressure, the film formation processing unit 41 introduces an argon gas in the chamber 2.

More specifically, the film formation processing unit 41 controls the flow-volume control gauge 271b of the sputter gas introducing portion 27 to introduce the argon gas at the predefined flow volume into the chamber 2. Consequently, the interior of the chamber 2 becomes arbitrary pressure.

Through the above-described processes, a film formation is started (S01: a film formation processing starting step). When the argon gas is introduced into the chamber 2 from the sputter gas introducing portion 27 and the interior of the chamber 2 becomes arbitrary pressure, a DC voltage is applied to the target 231 from the power supply device 24. The application of the DC voltage turns the sputter gas into plasma, producing ions. When the produced ions collide with the target 231, the particles of the film formation material of the target 231 are flied out, and the film formation is started. As the flied-out particles are deposited on the workpiece W mounted on stage 21, a thin film is formed on the workpiece W.

When the film formation is started, the storage unit 44 starts storing the temperature Te_in of the cooling water e and the temperature Te_out thereof (S02). That is, when the film formation is started, the temperatures Te of the cooling water e measured by the temperature sensors 237b and 238b (a temperature detecting step) are transmitted to the control device 4 at regular cycles. The storage unit 44 stores at least the temperature Te_in of the cooling water e and the temperature Te_out thereof in the predetermined time T1 and in the predetermined time T2, transmitted from the temperature sensors 237b and 238b.

When, for example, the control device 4 determines that the film formation to be performed from now is the first film formation, the temperature Te_in of the cooling water e and the temperature Te_out thereof in the time period from a time at which it is determined that film formation processing has started to a time at which the predetermined time T1 has elapsed are stored. Moreover, when the control device 4 determines that the film formation to be performed from now is the last film formation, the temperature Te_in of the cooling water e and the temperature Te_out thereof in the time period from a time at which it is determined that the film formation processing has ended to a time at which the predetermined time T2 has elapsed are stored.

The control device 4 retrieves, from the storage unit 44, the temperature Te_in and the temperature Te_out of the cooling water e in the predetermined time 12 from the time at which it is determined that the film formation processing has ended or in the predetermined time T1 from the time at which it is determined that the film formation processing has started.

The calculating unit 45 calculates the cooling water in/out temperature difference (S03: a calculating step). The cooling water in/out temperature difference is calculated from the temperature Te_out and the temperature Te_in, both retrieved from the storage unit 44. The difference is calculated from the temperature Te_out and from the temperature Te_in with the same elapsed time t. The calculated cooling water in/out temperature differences are arranged for each elapsed time t. Hence, a change pattern over time in temperature difference in the predetermined time T1 (T2) is acquired.

Meanwhile, the target 231 obtains heat from the heat source 234 (the produced plasma). For example, the ions produced from the plasma have energies. As such energies collide with the target 231, heat is transmitted to the target 231, and thus the temperature of the target 231 increases. In order to decrease the increasing temperature of the target 231, the cooling water e cools the target 231 through the target base 232 and through the bonding portion 233. The temperature of the cooling water e rises by an amount of heat taken from the target 231. Accordingly, when the film formation is started, the temperature of the cooling water e increases. That is, when the film formation is started, the temperature Te_out of the cooling water e after the cooling increases. For example, as indicated in the predetermined time T1 in FIG. 4, the cooling water in/out temperature difference gradually increases along with the film formation time.

At the beginning of the start of the film formation processing, a heat quantity obtained from the heat source 234 (an input heat quantity to the target 231) is larger than the cooling quantity by the cooling water e (the heat dissipation quantity by the cooling water e). Hence, the temperature of the target 231 increases. When the temperature of the target 231 increases, the cooling quantity by the cooling water e also increases. When the target 231 becomes a certain temperature, the input heat quantity to the target 231 and the heat dissipation quantity by the cooling water e are balanced. That is, the target 231 becomes the steady state. Consequently, the cooling water in/out temperature difference becomes constant.

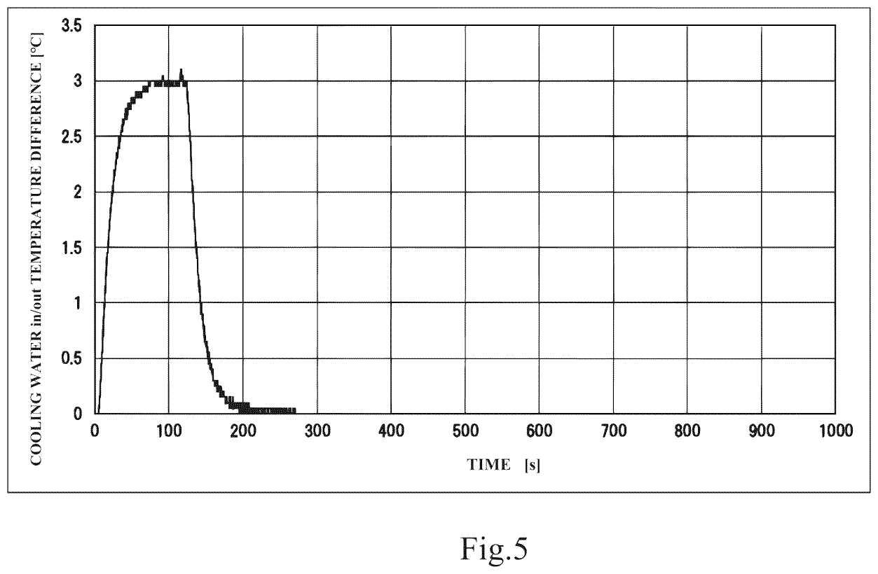

FIG. 5 is a graph showing the cooling water in/out temperature difference representing that the target 231 becomes the steady state by performing a steady operation for a certain time period. FIG. 5 shows the cooling water in/out temperature difference when the film formation (the film formation processing) was continuously performed for 120 seconds. As shown in FIG. 5, the cooling water in/out temperature difference becomes constant after 100 seconds from the start of the film formation processing. That is, the target 231 becomes the steady state after 100 seconds from the start of the film formation processing. As described above, the case in which the film formation time is short means a case in which the target 231 does not become the steady state. Accordingly, the case in which the film formation time is short represents a case in which, for example, the film formation is ended within a time period that is shorter than or equal to 100 seconds from the start of the film formation. Note that the condition in which the target 231 becomes the steady state varies depending on the material of the target 231 and on the film formation condition, etc. Hence, when the target 231 does not become the steady state in a case in which it exceeds 100 seconds from the start of the film formation, such a case included in the case in which the film formation time is short.

When the film formation has ended, plasma dissipates. Accordingly, since the heat source 234 dissipates, the heat introduced to the target 231 disappears. The cooling water e keeps cooling the target 231 through the target base 232 and through the bonding portion 233. Hence, the temperature of the target 231 decreases by heat dissipation by the cooling water e. As the temperature of the target 231 decreases, the temperature of the cooling water e after the cooling also decreases. That is, when the film formation has ended, the temperature Te_out of the cooling water e decreases. As indicated in, for example, the predetermined time T2 in FIG. 4, as time elapses from the end of the film formation processing, the cooling water in/out temperature difference gradually decreases.

The joined state determining unit 46 compares the change pattern of the calculated in/out temperature difference of the cooling water e with the change pattern of the in/out temperature difference of the cooling water e for the decent target, and determines the joined state of the target 231 (S04: a joined state determining step). FIG. 6 is a graph showing the change patterns of the in/out temperature difference of the cooling water e for a decent target and for a damaged target. Note that the damaged target means a target that has a peel-off occurred. As shown by a graph in a portion surrounded by a frame in FIG. 6, it is clear that, in the predetermined times T1 and T2, the slope in the temperature curve becomes large for the decent target, while the slope in the temperature curve for the damaged target is small. The joined state determining unit 46 calculates the slope of the calculated temperature curve of the in/out temperature difference, and calculates how much such a slope is similar to the slope of the decent target. Moreover, when the difference in the slope is within a certain value, it is determined that a large peel-off resulting in the falling of the target 231 has not occurred.

Here, a case in which a steady operation is performed for a certain time period and the target 231 reaches a steady state will be discussed. A case in which the target 231 reaches a steady state indicates, for example, in FIG. 5, a state of the in/out temperature difference of the cooling water e after 100 seconds from the start of the film formation processing. At this time, when a peel-off occurs at the bonding portion 233, since the thermal resistance of the bonding portion 233: increases, the in/out temperature difference of the cooling water e temporarily decreases. In a case in which the steady operation is performed for a certain time period, peel-off of the bonding portion 233 can be detected by using a temporary drop in temperature as a threshold.

However, it is difficult to set the threshold immediately after the start of the operation or when the film formation time is short even a steady operation is performed. When, for example, as shown in FIG. 4, the film formation time is short even the steady operation is performed, the in/out temperature difference of the cooling water e decreases during a time period until the start of the next film formation from the end of a given film formation. By using a method that sets a threshold, it is difficult to distinguish whether a reason for the decrease in the in/out temperature difference of the cooling water e is due to the end of the film formation or due to peel-off of the bonding portion 233.

### 1-3. Advantageous Effects

(1) The film formation apparatus 1 according to this embodiment includes the chamber 2 in which the workpiece W is carried, the target 231 placed in the chamber 2, the target base 232 that holds, on one surface, the target 231, a temperature detecting unit (the temperature sensors 237b and 238b) that detects the temperature of the target 231 and/or the target base 232 in the predetermined time T2 after the end of the film formation processing or in the predetermined time T1 from the start of the film formation processing after the certain time Tsp has elapsed from the end of the film formation processing, a calculating unit 45 that calculates a change in temperature over time in a predetermined time based on the detected temperature of the target 231 and/or the target base 232, and a joined state determining unit 46 that determines the joined state of the target 231 based on the change in temperature over time in the predetermined time.

According to this embodiment, the joined state of the target base 231 is determined based on the temperature change pattern of the target 231 in the predetermined time T1 or T2. That is, the state of the thermal resistance between the target 231 and the bonding portion 233 that is fastening the target base 232 is indirectly monitored by the temperature of the target 231. When a peel-off occurs in the target 231, the thermal resistance of the target 231 increases. Moreover, since a peel-off is detected based on the change pattern of the temperature over time in a certain time period that is the predetermined time T1 or T2, and a peel-off is not detected based on the state of the target 231 at a given time, a quite small peel-off at an initial stage can be detected.

Moreover, since a quite small peel-off at an initial stage is detectable, information on the joined state of the target 231 can be managed. For example, information on the joined state of the target 231 can be recorded in a recording medium, such as a bar code, a QR code or an IC tag, provided at a Front Opening Unified Pod (FOUP). By managing such information using the recording medium provided at the FOUP, even if a defect, such as the deterioration of the quality of a thin film formed on the workpiece W or nonuniformity of the film thickness, occurs, the cause thereof can be promptly identified and resolved. Furthermore, management of the information on the joined state of the target 231 enables a determination on a quite small peel-off at an initial stage that does not result in an occurrence of the defect and on a quite small peel-off at an initial stage that results in an occurrence of the defect. Hence, when a quite small peel-off at an initial stage that results in an occurrence of the defect occurs, since the film formation apparatus 1 can be suspended, the yield of the workpiece W can be improved.

In a case in which a peel-off is detected by only the state change of the target 231, e.g., the temperature of the target 231 at a given time, melting or a peel-off of the bonding portion 233 starts due to some reasons, and a quite small peel-off of the target 231 due to the melting or peel-off is not detectable. In such a case, the peel-off of the target 231 gradually advances while the target 231 is continuously utilized, and eventually, the target 231 falls in most cases. Hence, even if a problem is identified when the target 231 falls off, it is difficult to clarify the true cause of the peel-off in most cases. According to this embodiment, the state of the target 231 subjected to monitoring is compared with the measurement result for the decent target in a certain time period, i.e., the temperature change pattern. From a peel-off of the bonding portion 233 due to melting or stress, a peel-off of the target 231 is caused, and the thermal resistance of the target 231 increases, Since the joined state of the target 231 is detected by utilizing a difference in temperature change in the predetermined time T1 (or T2) due to the increase of the thermal change of the target 231, it becomes possible to detect a minor peel-off before the target 231 falls. Moreover, since a minor peel-off before the target 231 falls can be detected, it is possible to predict a timing at which the target 231 should be replaced and notify a user of timing for a necessary maintenance.

Moreover, although the target 231 is not heated to a temperature at which the bonding portion 233 melts, a peel-off of the target 231 may occur. It is thought that this may be caused by stress produced by a difference in thermal expansion between the target 231 and the bonding portion 233 or between the target base 232 and the bonding portion 233. According to this embodiment, when a peel-off of the target 231 occurs, it appears as the temperature change of the target 231 in the predetermined time T1 or T2, and thus a peel-off due to stress is also detectable.

Furthermore, according to this embodiment, the temperature change pattern of the decent target and that of the target 231 are compared with each other. Hence, even if it is difficult to set a threshold for a measured value (e.g., immediately after the start of the operation or a case in which the film formation time is short even a steady operation is performed), a minor peel-off before the target 231 falls is detectable. Moreover, since it becomes possible to identify whether such a peel-off occurs in the predetermined time T1 or T2, identification of the true cause resulting in the start of the peel-off of the target 231 is facilitated.
(2) According to this embodiment, the apparatus includes the cooling plate 235 which contacts the other surface of the target base 232, and in which the flow path 235f for the cooling water e is provided, the temperature detecting unit is the temperature sensors 237b and 238b provided at the water supply portion 237 and at the water drain portion 238, respectively, both portions being connected to the flow path 235f of the cooling plate 235, the temperature detecting unit detects the temperature of the target 231 and/or the target base 232 as the temperatures (the temperature Te_in and the temperature Te_out) of the cooling water e before and after the cooling, the calculating unit 45 calculates a change over time in temperature difference of the cooling water e before and after cooling in the predetermined time T1 or T2, the joined state determining unit 46 determines the joined state of the target 231 based on a change over time in temperature difference of the cooling water e before and after the cooling in the predetermined time T1 or T2.

The temperature of the target 231 is not measured directly, but indirectly measured measuring the temperatures Te_in of the cooling water e and the temperature Te_out thereof. Hence, it is unnecessary to newly install a temperature measuring device for the target 231 and for the target base 232. Accordingly, an occurrence of a measurement error due to such installment of a temperature measuring device is suppressed, and the apparatus can be adopted without a load to the user inherent to such an installation.

### 1-4. Modifications

(1) In the above-described embodiment, the joined state determining unit 46 detects the joined state of the target 231 by comparing the slope of the cooling water in/out temperature difference in the predetermined time T1 or T2 with the slope of the cooling water in/out temperature difference for the decent target. By separately determining the joined state of the target twice, i.e., in the predetermined times T1 and T2, it becomes easier to narrow down a time period at which the peel-off of the target 231 started, and it becomes easier to identify the true cause resulting in the start of the peel-off. On the other hand, instead of determining the joined state of the target 231 in both time periods that are the predetermined times T1 and T2, the joined state may be determined in only the predetermined time T1 or in only the predetermined time T2. Depending on the condition of the film formation and on the kind of the target, a difference may occur between the decent target and the damaged target only in either the predetermined time T1 or T2. In such a case, instead of determining the joined state in both time periods, the joined state may be determined in only either one predetermined time. In particular, by determining the joined state in the predetermined time T1, the joined state of the target 231 immediately after the start of the film formation processing can be determined. Hence, when a minor peel-off before the target 231 falls is detected, the film formation processing can be suspended promptly. This suppresses the falling of the target 231 during the film formation processing.

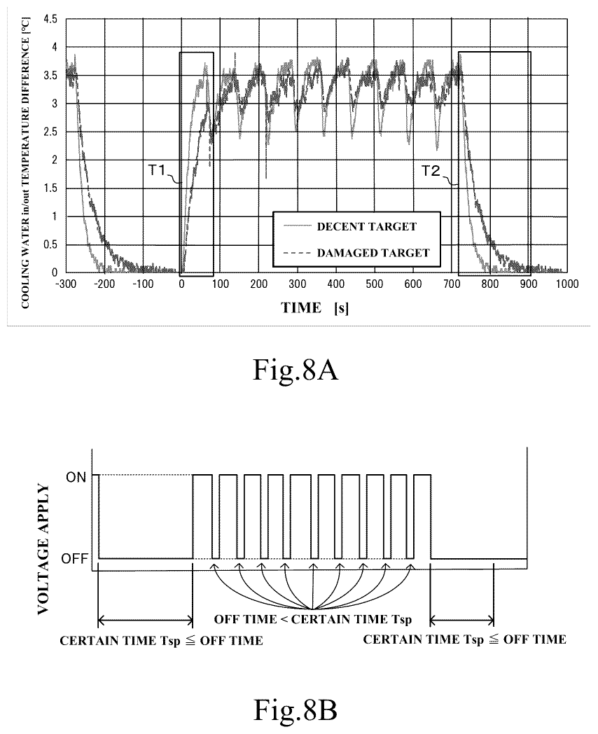

Moreover, the control device 4 may also store the application or non-application of the voltage to the target 231 by the power supply device 24 relative to the elapsed time t during S01 and S02. As for causing the control device 4 to recognize the “end of the film formation processing” and the “start of the film formation processing” after the certain time Tsp has elapsed from the end of the film formation processing, there is a method for monitoring an interval of the voltage application to the target 231 by the power supply device 24. FIG. 8A is a graph showing the change pattern of the in/out temperature difference of the cooling water e for a decent target and that for a damaged target. FIG. 8B is a graph which corresponds to the change pattern of the in/out temperature difference of the cooling water e in FIG. 8A, and which shows ON and OFF of the applied voltage by the power supply device 24. For example, as shown in FIG. 8B, it may be determined whether a time (an OFF time) until the start of the next DC voltage application to the target 231 after the DC voltage application to the target 231 by the power supply device 24 is terminated has elapsed by longer than or equal to the certain time Tsp or not. In this embodiment, since the certain time Tsp is 180 s, when greater than or equal to 180 s elapse after the DC voltage application to the target 231 is terminated, the end of the film formation immediately before a time point at which the certain time Tsp has elapsed is determined as the end of the film formation processing. Similarly, when the film formation starts after longer than or equal to the certain time Tsp (180 s) has elapsed from the situation in which the DC voltage application to the target 231 is terminated, it is determined as the start of the film formation processing.

Furthermore, instead of the slope of the cooling water in/out temperature difference in the predetermined time T1 or T2, a threshold (a first threshold) for a difference when the in/out temperature difference of the cooling water e for the damaged target is compared with the in/out temperature difference of the cooling water e for the decent target may be set, and the joined state of the target 231 may be determined by checking whether a time at which the difference in such a comparison becomes greater than or equal to the first threshold continues for a predetermined time or longer.

In the predetermined time T1, for example, the value of the in/out temperature difference of the cooling water e for the decent target becomes greater than the value of the in/out temperature difference of the cooling water e for the damaged target. Hence, a difference between the in/out temperature difference of the cooling water e for the decent target and the in/out temperature difference of the cooling water e for the damaged target is acquired. When a time at which the acquired difference becomes greater than or equal to the first threshold continues for an arbitrary predetermined time or longer, a determination may be made such that a minor peel-off before the target 231 falls has occurred.

Moreover, in the predetermined time T2, the value of the in/out temperature difference of the cooling water e for the decent target becomes smaller than the value of the in/out temperature difference of the cooling water e for the damaged target. Hence, a difference between the in/out temperature difference of the cooling water e for the decent target and the in/out temperature difference of the cooling water e for the damaged target is acquired. When a time at which the acquired difference becomes greater than or equal to the first threshold continues for an arbitrary predetermined time or longer, a determination may be made such that a minor peel-off before the target 231 falls has occurred. Note that in the predetermined time T1 and in the predetermined time T2, the first threshold with different values may be applied.
(2) In the above-described embodiment, the joined state determining unit 46 compares the calculated in/out temperature difference of the cooling water e for the target 231 with the in/out temperature difference of the cooling water e for the decent target, and determines the joined state of the target 231. However, the method of determining the joined state of the target in the joined state determining unit 46 is not limited to the above-described method.

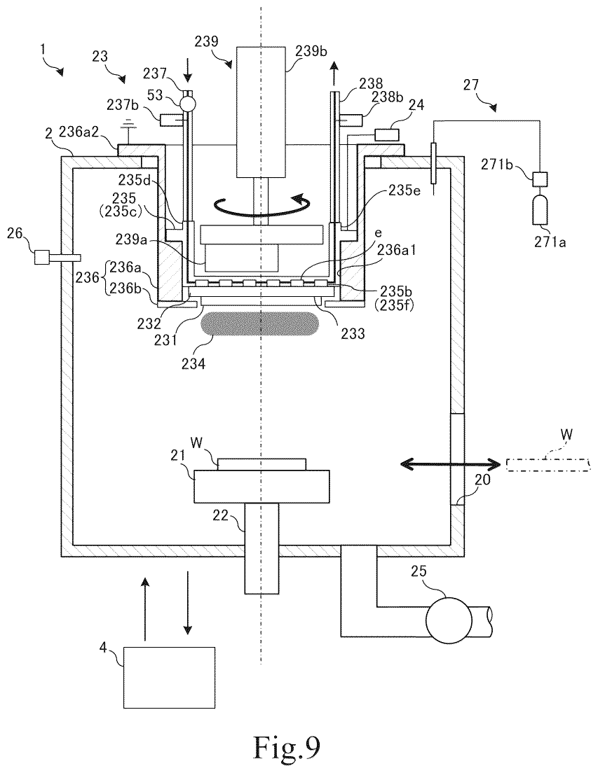

For example, as illustrated in FIG. 9, a flow-volume gauge 53 that measures the flow volume of the cooling water e flowing through the flow path 235f is provided, and the temperature (the temperature Te_in) of the cooling water e at the inlet, the temperature (the temperature Te_out) thereof at the outlet, and further the flow volume of the cooling water e are measured. A heat dissipation quantity J of the target 231 is calculated from the temperature (the temperature Te_in) of the cooling water e at the inlet, the temperature (the temperature Te_out) thereof at the outlet, and further the flow volume of the cooling water e. An integrated value of the heat dissipation quantity J (an integrated heat dissipation quantity G) in the predetermined time T1 and/or the predetermined time T2 may be calculated from the calculated heat dissipation quantity J, and may be compared with the integrated value for the decent target in the same time period so as to determine the joined state. Note that, in this embodiment, although the flow-volume gauge 53 is provided at the water supply portion 237, it may be provided at the water drain portion 238, or may be provided at both the water supply portion 237 and the water drain portion 238.

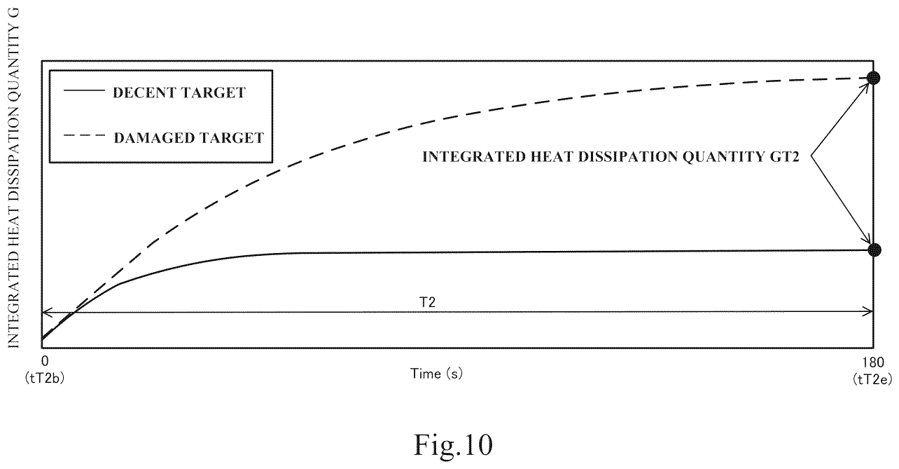

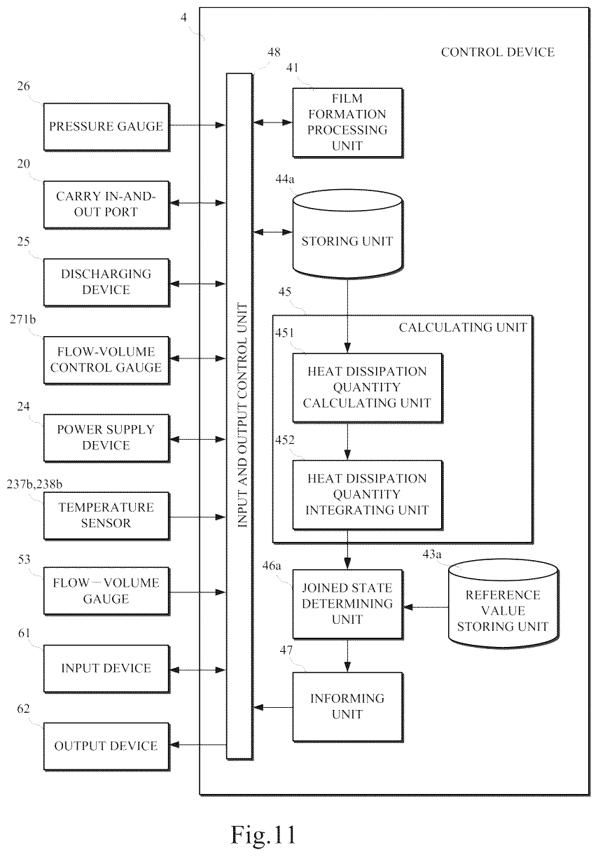

An example case will be described in which the joined state of the target 231 is determined from the integrated value of the heat dissipation quantity Jin predetermined time T2 with reference to FIG. 9, FIG. 10 and FIG. 11. A storage unit 44a stores the flow volume of the cooling water e from the flow-volume gauge 53 in addition to the temperature Te_in of the cooling water e and the temperature Te_out thereof. The calculating unit 45 includes a heat dissipation quantity calculating unit 451 and a heat dissipation quantity integrating unit 452. The heat dissipation quantity calculating unit 451 calculates the heat dissipation quantity J of the target 231 in an elapsed time t from the temperature change of the target 231 over time in the predetermined time T2 which is calculated from the temperature Te_in and the temperature Te_out of the cooling water e in the predetermined time T2, and from the flow volume of the cooling water e. Furthermore, the heat dissipation quantity integrating unit 452 integrates the heat dissipation quantities J, calculates the integrated heat dissipation quantity G relative to the elapsed time t, and calculates an integrated heat dissipation quantity GT2 (GT1) in the predetermined time T2 (T1). That is, the heat dissipation quantity calculating unit 451 calculates a change over time in the integrated heat dissipation quantity G in the predetermined time T1 and/or the predetermined time T2.

A reference value storing unit 43a stores the integrated heat dissipation quantity GT2 (GT1) of the decent target in the predetermined time T2 (T1) in advance. A joined state determining unit 46a determines the joined state by comparing the integrated heat dissipation quantity GT2 (GT1) of the decent target in the predetermined time T2 (T1) with the integrated heat dissipation quantity GT2 (GT1) calculated from the target 231. That is, the joined state determining unit 46a determines the joined state of the target 231 based on a change over time in the integrated heat dissipation quantity G in the predetermined time T1 and/or the predetermined time T2.

FIG. 10 is a graph showing a change pattern of the integrated heat dissipation quantity GT2 for a decent target in the predetermined time T2 and that for a damaged target. In FIG. 10, a start time tT2b of the predetermined time T2 is set to be zero, and an end time tT2e of the predetermined time T2 is set to be 180 s. Moreover, at the start time tT2b of the predetermined time T2, the integrated heat dissipation quantity GT2 is set to be the same value as that of the heat dissipation quantity J at the start time tT2b of the predetermined time T2. In this embodiment, the integrated heat dissipation quantity GT2 in the predetermined time T2 to determine the joined state is set to be the integrated heat dissipation quantity GT2 at the end time tT2e of the predetermined time T2. When the joined state of the target 231 is to be determined from the integrated heat dissipation quantity GT2 in the predetermined time T2, the heat dissipation quantities J in the predetermined time T2 are integrated, and thus the integrated heat dissipation quantity GT2 in the predetermined time T2 is calculated. In this case, the value of the integrated heat dissipation quantity GT2 in the case of a large peel-off is acquired in advance by experiments, and a small value of the integrated heat dissipation quantity G with a margin relative to the acquired value is set to be a value that becomes an index for a minor peel-off before the target 231 falls. Accordingly, detection of a peel-off at a time point at which it becomes a value that is an index for a minor peel-off before the target 231 falls can prevent the target 231 from falling.

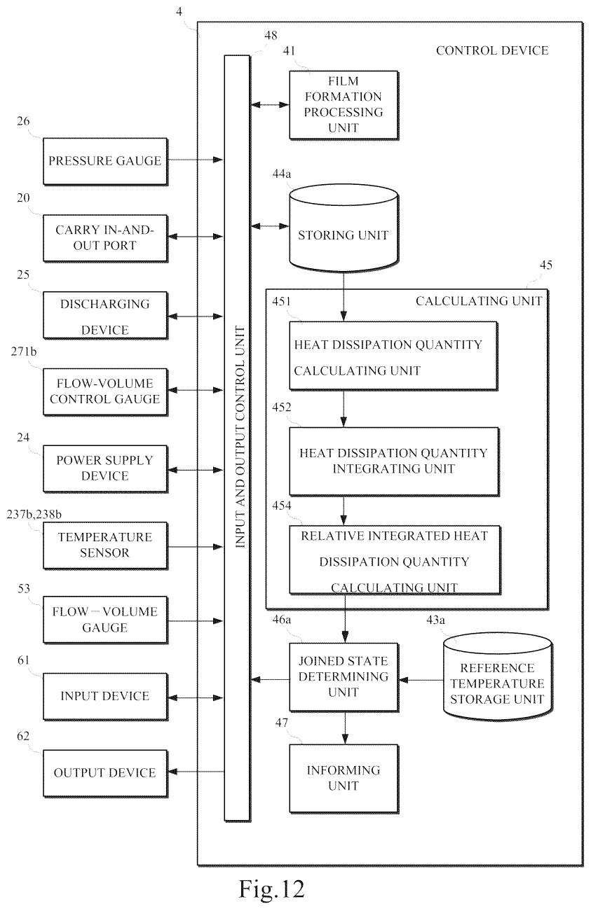

The joined state is determined by the joined state determining unit 46a that compares the integrated heat dissipation quantity GT2 of the decent target in the predetermined time T2 stored in the reference value storing unit 43a in advance with the integrated heat dissipation quantity GT2 calculated from the target 231. For example, a peel-off of the target 231 may be detected based on whether a difference between the integrated heat dissipation quantity GT2 calculated from the target 231 and the integrated heat dissipation quantity GT2 of the decent target is higher or lower than a threshold (a second threshold). The same may be performed for the predetermined time T1. When, however, the film formation condition differs even the material of the target 231 is consistent, the integrated heat dissipation quantity GT2 becomes also different. It is preferable to make a determination by the above-described method when the film formation condition is consistent.
(3) Moreover, instead of directly comparing the respective integrated heat dissipation quantities G, with reference to an integrated heat dissipation quantity Gt after a predetermined time tc that is a reference has elapsed, a heat dissipation ratio that is a relative value of the integrated heat dissipation quantity G for each elapsed time t relative to the integrated heat dissipation quantity Gt may be acquired, and the joined state may be determined based on this heat dissipation ratio. As illustrated in FIG. 12, the calculating unit 45 further includes a relative integrated heat dissipation quantity calculating unit 454. With the integrated heat dissipation quantity Gt after 180 seconds have elapsed from the end of the film formation processing being taken as “1”, the relative integrated heat dissipation quantity calculating unit 454 calculates the relative value (the heat dissipation ratio) of the integrated heat dissipation quantity G relative to the elapsed time t (an elapsed time t after a heat input is terminated) from the end of the film formation processing. That is, the relative integrated heat dissipation quantity calculating unit 454 obtains the integrated heat dissipation quantity G relative to the elapsed time t with reference to the integrated heat dissipation quantity Gt after the predetermined time tc has elapsed and calculated by the heat dissipation quantity integrating unit 452.

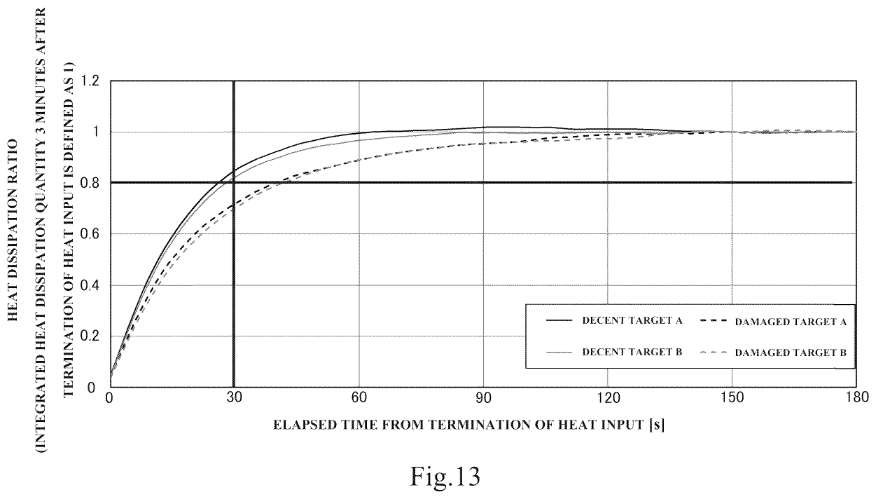

FIG. 13 is a graph showing a heat dissipation ratio relative to the elapsed time t after a heat input is terminated. In FIG. 13, a continuous line represents a change in heat dissipation ratio relative to the elapsed time t from the termination of heat input for a decent target, and a dotted line represents a change in heat dissipation ratio relative to the elapsed time t from the termination of heat input for the target 231 (a damaged target) that has a peel-off occurring at the bonding portion 233. It becomes clear that, in the case of the decent target, although the heat dissipation ratio exceeds 0.8 after 30 seconds from the end of the film formation processing (i.e., from the termination of heat input), in the case of the target 231 that has a peel-off occurring at the bonding portion 233, the value of the heat dissipation ratio after 30 seconds from the end of the film formation processing (i.e., from the termination of heat input) is lower than 0.8.

For example, the heat dissipation ratio after 30 seconds from the end of the film formation processing (i.e., from the termination of heat input) may be calculated, and a peel-off of the target 231 may be detected based on whether the calculated value is higher or lower than 0.8 (the second threshold). As for the second threshold, for example, a heat dissipation ratio after 30 seconds from the end of the film formation processing (i.e., from the termination of heat input) in the case of a large peel-off is acquired in advance by experiment, and a larger value with a margin than such a value is set as a value that becomes an index for a minor peel-off. Hence, detection of a peel-off at a time point at which it becomes the value that is an index for a minor peel-off prevents the target 231 from falling.

According to this modification, the joined state determining unit 46a determines the joined state of the target 231 based on the relative value calculated by the relative integrated heat dissipation quantity calculating unit 454. Since the joined state is determined based on the heat dissipation ratio, a detection of a peel-off is enabled by a comparison with the second threshold. This reduces a work burden for creating a program for the joined state determination. Moreover, when the film formation condition differs and the value of the integrated heat dissipation quantity GT2 of the decent target and that of the integrated heat dissipation quantity GT2 of the target 231 are also different, a comparison based on the heat dissipation ratio is possible. This facilitates the comparison of the integrated heat dissipation quantity G between the targets with different film formation conditions.

### 2. Second Embodiment

### 2-1. Structure

A second embodiment according to the present disclosure will be described with reference to the figures. The similar component to that of the first embodiment will be denoted by the same reference numeral, and the description thereof will be omitted.

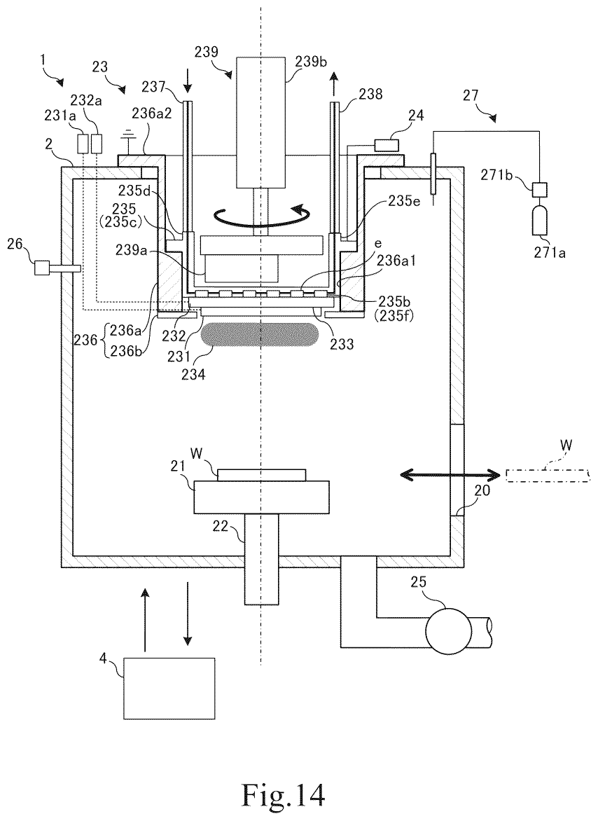

As illustrated in FIG. 14, the film formation apparatus 1 according to this embodiment includes a temperature sensor 231a that detects a temperature TTGT of the target 231, and a temperature sensor 232a that detects a temperature Tbase of the target base 232, both sensors corresponding to the temperature detecting unit. As for the temperature sensor 231a and the temperature sensor 232a, for example, a thermocouple is applicable. The temperature sensor 231a and the temperature sensor 232a detect the temperature of the target 231 and that of the target base 232, respectively, in the predetermined time T2 after the end of the film formation processing or in the predetermined time T1 from the start of the film formation processing after the certain time Tsp has elapsed from the end of the film formation processing. Note that the temperature TTGT of the target 231 will be also referred to as the temperature TTGT, and the temperature Tbase of the target base 232 will be also referred to as the temperature Tbase.

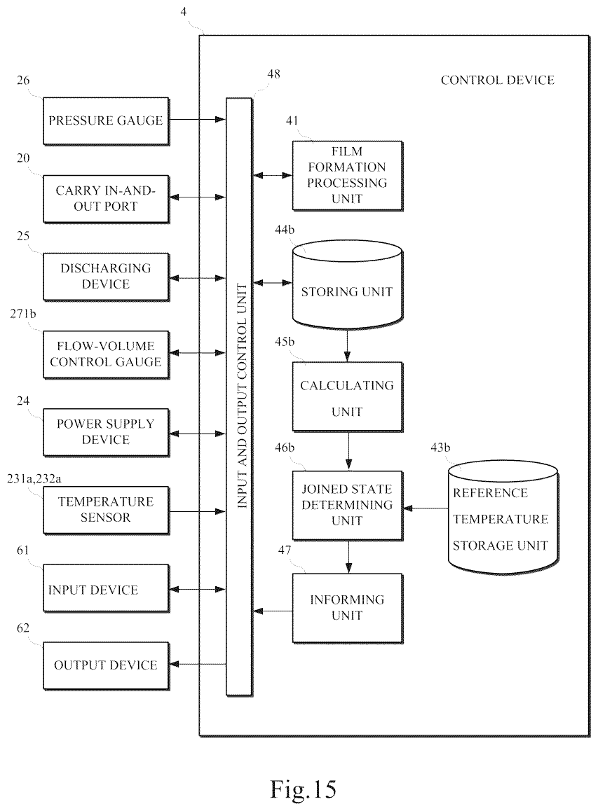

A structure of the control device 4 will be described with reference to FIG. 15 that is a virtual functional block diagram. The control device 4 includes the film formation processing unit 41, a reference temperature storing unit 43b, a storage unit 44b, a calculating unit 45b, a joined state determining unit 46b, the informing unit 47, and the input and output control unit 48. Note that the control device 4 is connected to the input device 61 and to the output device 62 like the first embodiment.

The reference temperature storing unit 43b calculates and stores a procedure of the temperature decrease of the target 231 that is a decent target which has no heat input, and that of the target base 232 from a state (a steady state) in which the heat input and the heat dissipation are balanced with each other for the decent target. For example, the temperature Tbase of the target base 232 relative to the temperature TTGT of the target 231 is stored for each elapsed time t until 300 seconds have elapsed after the end of the film formation processing for the decent target.

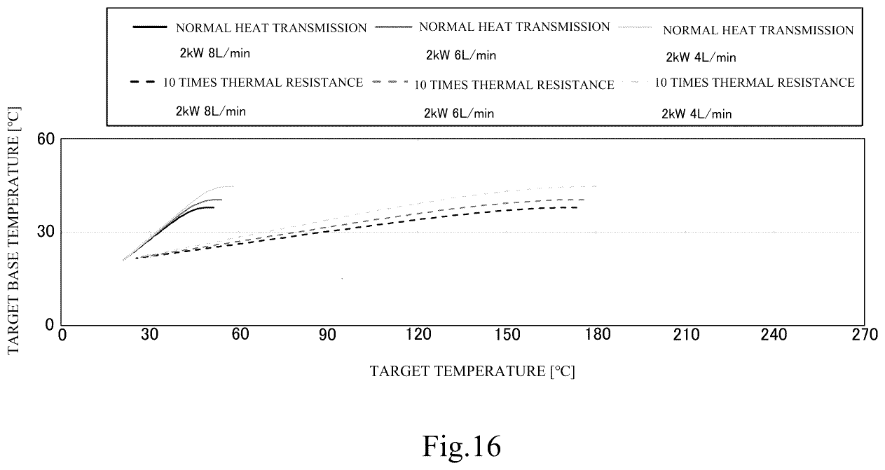

FIG. 16 is a graph showing a simulation for a correlation between the temperature TTGT of the target 231 and the temperature Tbase of the target base 232 after the film formation processing using a Cr target that is φ150 mm×t 10 mm, both temperatures changing over time. In other words, FIG. 16 is a graph showing a simulation for a correlation between the temperature TTGT of the target 231 and the temperature Tbase of the target base 232 both in the predetermined time T2. In FIG. 16, the temperature TTGT of the target 231 is taken as an X-axis, and the temperature Tbase of the target base 232 is taken as a Y-axis. The continuous line represents the temperature Tbase of the target base 232 relative to the temperature TTGT of the target 231 that is a decent target which has no peel-off occurring when the simulation was made with the applied voltage and the flow volume of the cooling water e being changed. Moreover, the dotted line represents the temperature Tbase of the target base 232 relative to the temperature TTGT of the target 231 that has the thermal resistance increased by 10 times with an assumption for the target 231 which has a peel-off occurring and which has the thermal resistance thus increased.

As shown in FIG. 16, according to the plots (the dotted line) for a case in which a peel-off is assumed, in comparison with a decent target, the temperature TTGT of the target 231 becomes higher than the temperature Tbase of the target base 232 at any flow volume of the cooling water e. It is thought that this is because transmission of heat input from the heat source 234 to the target base 232 becomes difficult since the thermal resistance increases due to a peel-off for the target 231 that has such a peel-off occurring. That is, the slope of the temperature change is acquired from the plots of the temperature Tbase of the target base 232 relative to the temperature TTGT of the target 231 which changes over time in the predetermined time T2 after the film formation processing, and comparison of the acquired result with that of the decent target enables a determination on the joined state of the target 231.

The storage unit 44b stores the temperature TTGT of the target 231 that is detected by the temperature sensor 231a, and the temperature Tbase of the target base 232 that is detected by the temperature sensor 232a. When the film formation is started, the temperature TTGT of the target 231 and the temperature Tbase of the target base 232 are transmitted to the control device 4. The storage unit 44b stores the temperature TTGT of the target 231 and the temperature Tbase of the target base 232, both changing over time in the predetermined times T1 and T2. Note that the storage unit 44b may store the temperature TTGT of the target 231 and the temperature Tbase of the target base 232 in a time period from the start of the film formation process to the end of the film formation process. Alternatively, the storage unit 44b may store the temperature TTGT of the target 231 and the temperature Tbase of the target base 232 while the film formation apparatus 1 is in operation.

The calculating unit 45b calculates the temperature Tbase of the target base 232 relative to the temperature TTGT of the target 231 from the temperature TTGT and the temperature Tbase, both stored in the storage unit 44b. That is, the calculating unit 45b correlates the temperature Tbase of the target base 232 with the temperature TTGT of the target 231, both changing over time in the predetermined time T2 (T1). Hence, the value of the temperature Tbase of the target base 232 relative to the temperature TTGT of the target 231 in the predetermined time T2 (T1) is acquired. The value of the temperature Tbase of the target base 232 relative to the temperature TTGT of the target 231 in the predetermined time T2 (T1) also included in a change in temperature over time in the predetermined time T2 (T1). The temperature Tbase of the target base 232 relative to the temperature TTGT of the target 231 calculated by the calculating unit 45b for each elapsed time t may be acquired in only either one of or both of the predetermined time T1 and the predetermined time T2, in the following description, in order to facilitate understanding to the present disclosure, an example case will be described in which the temperature Tbase of the target base 232 relative to the temperature TTGT of the target 231 in the predetermined time T2 (until 300 seconds have elapsed from the end of the film formation processing).

The joined state determining unit 46b determines the joined state of the target 231 based on the correlation between the temperature Tbase of the target base 232 and the temperature TTGT of the target 231, both changing over time in the predetermined time T2. That is, the joined state determining unit 46b compares the temperature Tbase of the target base 232 relative to the temperature TTGT of the target 231 calculated for each elapsed time t in the predetermined time T2 from the target 231 with the temperature Tbase of the target base 232 relative to the temperature TTGT of the target 231 for each elapsed time t in the predetermined time T2 for the decent target stored in the reference temperature storing unit 43b, and which determines the joined state of the target.

### 2-2. Actions

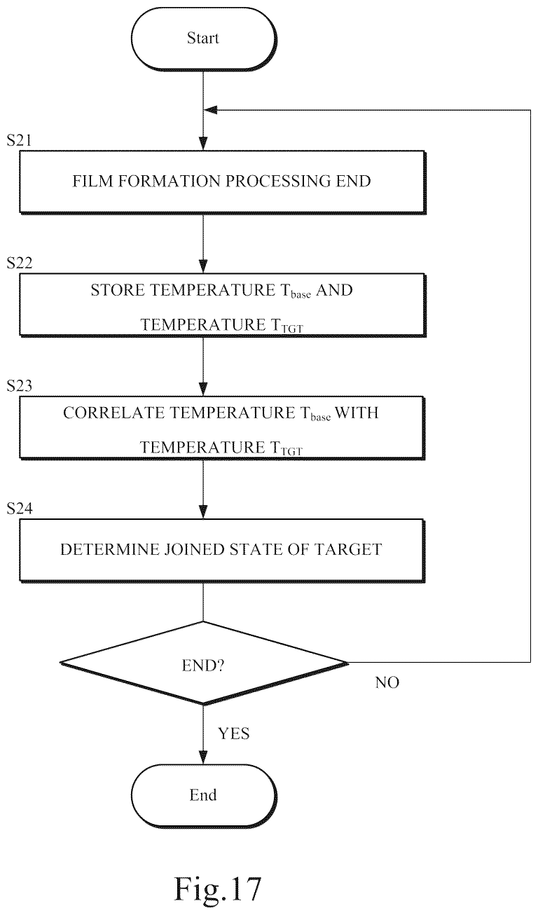

Next, operations of the film formation apparatus 1 according to this embodiment and a film formation method thereof will be described with reference to FIG. 17.

When film formation processing ends (S21: a film formation processing ending step), the temperature TTGT and the temperature Tbase are stored (S22: a temperature detecting step). Transmitted to the control device 4 at regular cycles are the temperature TTGT and the temperature Tbase which are detected by the temperature sensor 231a and the temperature sensor 232a, respectively. The storage unit 44 stores the temperature TTGT and the temperature Tbase.

The calculating unit 45 correlates the temperature Tbase with the temperature TTGT in the predetermined time T2 (S23: a calculating step). That is, heat input and heat discharge regarding the target 231 are present during the film formation, but when the film formation processing has ended, the target 231 is no longer heated, and thus the target 231 and the target base 232 gradually decrease respective temperatures. The calculating unit 45 arranges the temperature Tbase and the temperature TTGT side by side for each elapsed time t, and thus the change pattern of the temperature Tbase relative to the temperature TTGT in the predetermined time T2 is acquired.

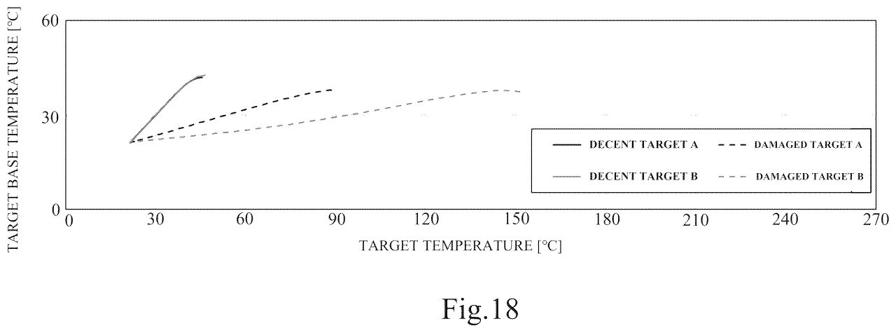

The joined state determining unit 46 compares the calculated change pattern of the temperature Tbase of the target base 232 relative to the temperature TTGT of the target 231 with the change pattern of the temperature Tbase of the target base 232 relative to the temperature TTGT of the target 231 that is a decent target, and determines the joined state of the target 231 (S24: a joined state determining step), FIG. 18 is graph showing a correlation between the temperature TTGT of the target 231 and the temperature Tbase of the target base 232. FIG. 18 shows the temperature Tbase of the target base 232 relative to the temperature TTGT of the target 231 for each target 231 in a different state. When FIG. 18 is compared with FIG. 16, the change pattern of the temperature Tbase of the target base 232 relative to the temperature TTGT of the target 231 is consistent. In view of the foregoing, it is thought that the temperature change of the target 231 and that of the target base 232 are caused due to an increase in thermal resistance of the target 231. Moreover, as shown in the graph of FIG. 18, in the case of a decent target, although the absolute value of the slope in the temperature curve in the graph increases, in the case of a damaged target, the absolute value of the slope in the temperature curve decreases.

The joined state determining unit 46b calculates the slope of the temperature Tbase of the target base 232 relative to the temperature TTGT of the target 231, and calculates how much such a slope is similar to the slope for the decent target. Next, when the difference in slope is within a certain value, a determination is made such that a peel-off has not occurred. For example, the absolute value of the “slope of the temperature curve” in the case of a large peel-off is acquired in advance by experiments, and a value which has a margin from the foregoing value, and which becomes a larger value in absolute value is set as a value that becomes an index for a minor peel-off. Accordingly, when a peel-off is detected at a time point at which it becomes the value that is an index for a minor peel-off, the target 231 can be prevented from falling. Moreover, a difference between the value that is an index for a minor peel-off with the absolute value of the slope of the temperature curve for the decent target may be acquired, and a determination may be made such that a peel-off has not occurred when such a difference in slope is within the set value. Note that although a method of calculating the slope of the temperature Tbase of the target base 232 relative to the temperature TTGT of the target 231 in the predetermined time T2 has been described, the joined state determining unit 46b can determine the joined state of the target 231 even by calculating the slope of the temperature Tbase of the target base 232 relative to the temperature TTGT of the target 231 in the predetermined time T1.

### 2-3. Advantageous Effects

(1) In this embodiment, the joined state of the target 231 is determined based on a correlation between the temperature Tbase and the temperature TTGT, both changing over time in the predetermined time T1 or T2. That is, the state of the thermal resistance of the bonding portion 233 that fastens the target 231 with target base 232 is monitored by directly measuring the temperature Tbase and the temperature TTGT. When a peel-off occurs on the target 231, the thermal resistance of the target 231 increases, Hence, like the first embodiment, instead of detecting a peel-off based on the state of the target 231 at a given time, the joined state is determined based on a correlation between the temperature Tbase and the temperature TTGT, both changing over time in a certain time period that is the predetermined time T1 or T2, i.e., the temperature change pattern. This enables a detection of a quite small peel-off at an initial stage.

Moreover, since a quite small peel-off at an initial stage is detectable, information on the joined state of the target 231 may be stored in a recording medium provided on the FOUP. This enables a management of the information on the joined state of the target 231. Accordingly, even if a defect, such as the deterioration of the quality of a thin film formed on the workpiece W or nonuniformity of the film thickness, occurs, the cause thereof can be promptly identified and resolved. Furthermore, since the quality of a thin film formed on the workpiece W can be managed, the yield of the workpiece W can be improved. Still further, by managing the information on the joined state of the target 231, it is possible to predict a timing to replace the target 231 and notify a user of the timing when maintenance is necessary,

### 3. Other Embodiments

Although the embodiments and the modifications of the components according to the present disclosure have been described, those embodiments and modifications are merely presented as examples, and are not intended to limit the scope of the present disclosure. The above-described novel embodiments can be carried out in other various forms, and various omissions, replacements and modifications can be made without departing from the scope and spirit of the present disclosure, Such embodiments and modifications are within the scope and spirit of the present disclosure, and included in the invention as recited in the appended claims.

REFERENCE SIGN

| | |
|---|---|
| 1 | Film formation apparatus |
| 2 | Chamber |
| 4 | Control device |
| 20 | Carry in-and-out port |
| 21 | Stage |
| 22 | Shaft |
| 23 | Sputter source |
| 231 | Target |
| 231a | Temperature sensor |
| 232 | Target base |
| 232a | Temperature sensor |
| 233 | Bonding portion |
| 234 | Heat source |
| 235 | Cooling plate |
| 235a | Sealing member |
| 235b | Groove |
| 235b1 | Inlet |
| 235b2 | Outlet |
| 235c | Flange |
| 235d | Water supply opening |
| 235e | Water drain opening |
| 235f | Flow path |
| 236 | Anode portion |
| 236a | T-S Distance adjusting portion |
| 236a1 | Thickened portion |
| 236a2 | Flange |
| 236b | Anode ring |
| 237 | Water supply portion |
| 237b | Temperature sensor |
| 238 | Water drain portion |
| 238b | Temperature sensor |
| 239 | Magnet portion |
| 239a | Magnet |
| 239b | Motor |
| 24 | Power supply device |
| 25 | Discharging device |
| 26 | Pressure gauge |
| 27 | Sputter gas introducing portion |
| 271a | Argon gas introducing portion |
| 271b | Flow-volume control gauge |
| 41 | Film formation processing unit |
| 43, 43b | Reference temperature storing unit |
| 43a | Reference value storage unit |
| 44, 44a, 44b | Storing unit |
| 45, 45b | Calculating unit |
| 451 | Heat dissipation quantity calculating unit |
| 452 | Heat dissipation quantity integrating unit |
| 454 | Relative integrated heat dissipation quantity calculating unit |
| 46, 46a, 46b | Joined state determining unit |
| 47 | Informing unit |
| 48 | Input and output control unit |
| 53 | Flow-volume gauge |
| 61 | Input device |
| 62 | Output device |
| J | Heat dissipation quantity |
| G, Gt, GT2 | Integrated heat dissipation quantity |
| t | Elapsed time |
| T1, T2 | Predetermined time |
| Tbase | Target-based temperature |
| Tsp | Certain time |
| TTGT | Temperature of target |
| Te | Temperature of cooling water |
| W | Workpiece |

1. A film formation apparatus that performs film formation on a workpiece utilizing plasma comprises:
a sealed container in which the workpiece is carried;
a target placed in the sealed container;
a target base that holds, on one surface, the target;
a temperature detecting unit that detects a temperature of the target and/or the target base in a predetermined time after an end of film formation processing or in a predetermined time from a start of the film formation processing after a certain time has elapsed from the end of the film formation processing;
a calculating unit that calculates a change in temperature over time in the predetermined time based on the detected temperature of the target and/or the target base; and
a joined state determining unit that determines a joined state of the target based on the change in temperature over time in the predetermined time.

2. The film formation apparatus according to claim 1, further comprising a cooling plate which contacts an other surface of the target base, and in which a flow path for a cooling water is provided, wherein:
the temperature detecting unit includes temperature sensors provided at a water supply portion and at a water drain portion, respectively, both portions being connected to the flow path of the cooling plate;
the temperature detecting unit detects the temperature of the target and/or the target base as the temperatures of the cooling water before and after cooling;
the calculating unit calculates a change over time in temperature difference of the cooling water before and after the cooling in the predetermined time; and
the joined state determining unit determines the joined state of the target based on the change over time in temperature difference of the cooling water before and after the cooling in the predetermined time.

3. The film formation apparatus according to claim 2, further comprising a flow-volume gauge that measures a flow volume of the cooling water flowing through the flow path, wherein:
the calculating unit comprises:
a heat dissipation quantity calculating unit that calculates a heat dissipation quantity of the target in an elapsed time from the temperature change of the target over time in the predetermined time, and the flow volume of the cooling water; and
a heat dissipation quantity integrating unit which integrates the heat dissipation quantities, and which calculates an integrated heat dissipation quantity in the predetermined time,
the calculating unit calculates a change in the integrated heat dissipation quantity over time in the predetermined time; and
the joined state determining unit determines the joined state of the target based on the change in the integrated heat dissipation quantity over time.

4. The film formation apparatus according to claim 3, wherein:
the calculating unit further comprises a relative integrated heat dissipation quantity calculating unit that calculates a relative value of the integrated heat dissipation quantity relative to the elapsed time with reference to the integrated heat dissipation quantity after the predetermined time has elapsed and calculated by the heat dissipation quantity integrating unit; and
the joined state determining unit determines the joined state of the target based on the relative value calculated by the relative integrated heat dissipation quantity calculating unit.

5. The film formation apparatus according to claim 1, wherein:
the temperature detecting unit detects the temperatures of the target and the target base in the predetermined time after the end of film formation processing or in the predetermined time from the start of the film formation processing after the certain time has elapsed from the end of the film formation processing;
the calculating unit correlates the temperature of the target base with the temperature of the target, both temperatures changing over time in the predetermined time; and
the joined state determining unit determines the joined state of the target based on a correlation between the temperature of the target and the temperature of the target base, both temperatures changing over time.

6. A target joined state detecting method of a film formation apparatus that performs film formation on a workpiece utilizing plasma, the method comprising:
a temperature detecting step of detecting a temperature of the target and/or a target base in a predetermined time after an end of film formation processing or in predetermined time from a start of the film formation processing after a certain time has elapsed from the end of the film formation processing;
a calculating step of calculating a change in temperature over time in the predetermined time based on the detected temperature of the target and/or the target base; and
a joined state determining step of determining a joined state of the target based on the change in temperature over time in the predetermined time.
